(19) United States
(12) Patent Application Publication
(10) Pub. No.: US 2012/0104467 A1
(43) Pub. Date: May 3, 2012

(54) SELF-ALIGNED CONTACT STRUCTURE TRENCH JFET

(75) Inventors: Tiesheng Li, San Jose, CA (US); Ognjen Milic, San Jose, CA (US); Lei Zhang, Chengdu (CN)

(73) Assignee: Monolithic Power Systems, Inc., San Jose, CA (US)

(21) Appl. No.: 12/916,270

(22) Filed: Oct. 29, 2010

(51) Int. Cl. H01L 29/80; H01L 21/337

(52) U.S. Cl. 257/256; 438/186; 257/E29.31; 257/E21.445

(57) ABSTRACT

According to one embodiment, a self-aligned trench structure junction gate field-effect transistor (JFET) includes a silicon substrate, two or more trenches having a P-type polysilicon gate region near a bottom portion of the trench and an interlayer dielectric layer (ILDL) above the P-type polysilicon gate region, a channel region separating each trench including epitaxial silicon, an N+ source region above the channel region extending between a top of each trench, and a source metal above the N+ source region. In another embodiment, a self-aligned trench structure JFET includes a silicon substrate, two or more trenches having an N-type polysilicon gate region near a bottom portion of the trench and an ILDL above the N-type polysilicon gate region, a channel region separating each trench including epitaxial silicon, a P+ source region above the channel region extending between a top of each trench, and a source metal above the P+ source region.

### FIELD OF THE INVENTION

The present invention relates generally to a junction gate field-effect transistor (JFET), and particularly to a compact trench JFET and methods of production thereof.

### BACKGROUND

A conventional n-channel junction gate field-effect transistor (JFET) 100, as shown in FIG. 1, includes an n-type source region 102 comprising N+ material, a p-type gate region 104 comprising P-type polysilicon, a P+ implanted region 106, and a drain 118 comprising N+ material, which is generally a substrate. The material between the substrate drain 118 and the trenches 116 is typically an N epitaxial region 120. The P+ implanted region 106 is generally formed by diffusion of a material into the trench 116 in which the P-type polysilicon is formed. The source region 102 must be a minimum distance d away from the P-type polysilicon in order to properly function. When a gate voltage is applied to the gate region 104, a field will deplete and the channel 108 will be pinched off, thereby closing the “gate.” In order to maintain the distance d between the source region 102 and the P-type polysilicon for proper functioning of the JFET 100, the JFET 100 must be large.

In addition, a source metal 112 is provided above the oxide layers 114 and a tungsten plug 110. The tungsten plug 110 is used to connect the N+ material in the source region 102 and the source metal 112.

In addition, a source metal 112 is provided above the oxide layers 114 and a tungsten plug 110. The tungsten plug 110 is used to connect the N+ material in the source region 102 and the source metal 112. There are also contact areas between the source region 102, the drain 118, and the gate region 104.

The critical dimension of the JFET is the gate length d. This gate length d limits the performance of conventional JFET devices, since channel length is substantially larger than the minimum gate length size. In addition, the capacitances of the vertical sidewalls of the gate diffusion to drain and source regions are also quite large.

Thus, it would be advantageous to provide a JFET in which a minimum distance between the source region and drain could be maintained while the overall size of the JFET is reduced.

### SUMMARY OF INVENTION

According to one embodiment, a self-aligned trench structure junction gate field-effect transistor (JFET) includes a silicon substrate, two or more trenches having a P-type polysilicon gate region near a bottom portion of the trench and an interlayer dielectric layer (ILDL) above the P-type polysilicon gate region, a channel region separating each trench including epitaxial silicon, an N+ source region above the channel region extending between a top of each trench, and a source metal above the N+ source region.

In another embodiment, a self-aligned trench structure JFET includes a silicon substrate, two or more trenches having an N-type polysilicon gate region near a bottom portion of the trench and an ILDL above the N-type polysilicon gate region, a channel region separating each trench including epitaxial silicon, a P+ source region above the channel region extending between a top of each trench, and a source metal above the P+ source region.

In accordance with another embodiment, a method for producing a self-aligned trench structure JFET includes applying a mask to a substrate wherein the mask leaves portions of the substrate exposed, forming a trench in the exposed portions of the substrate, implanting a dopant into a bottom portion of the trench to form a P+ region, removing the mask, depositing a polysilicon into the trench, removing the polysilicon deposited above the top surface of the substrate, etching the polysilicon in the trench such that the polysilicon is recessed from a top surface of the substrate, depositing an ILDL into the trench above the polysilicon, forming a N+ source layer above the top surface of the substrate, and forming a source metal layer above the N+ source layer.

In another embodiment, a method for producing a self-aligned trench structure JFET includes applying a mask to a substrate wherein the mask leaves portions of the substrate exposed, forming a trench in the exposed portions of the substrate, implanting a dopant into a bottom portion of the trench to form a N+ region, removing the mask, depositing a polysilicon into the trench, removing the polysilicon deposited above the top surface of the substrate, etching the polysilicon in the trench such that the polysilicon is recessed from a top surface of the substrate, depositing an ILDL into the trench above the polysilicon, forming a P+ source layer above the top surface of the substrate, and forming a source metal layer above the P+ source layer.

### BRIEF DESCRIPTION OF THE DRAWINGS

The present invention can be further understood with reference to the following detailed description and the appended drawings, wherein like elements are provided with like reference signs.

FIG. 1 illustrates a conventional junction gate field-effect transistor (JFET) according to the prior art.

FIG. 2 illustrates a JFET according to one embodiment.

FIG. 3 is a flowchart of a method for producing a JFET, according to one embodiment.

### DETAILED DESCRIPTION

One problem associated with conventional junction gate field-effect transistors (JFETs) is in maintaining enough breakdown voltage, which forces the N+ of the source region to be far enough away from the P-type polysilicon of the gate region. If the N+ source region is too close, the voltage sustained by the channel in between is too little. Because of this, conventional JFETs had to be very big.

According to one general embodiment, a self-aligned trench structure junction gate field-effect transistor (JFET) includes a silicon substrate, two or more trenches having a P-type polysilicon gate region near a bottom portion of the trench and an interlayer dielectric layer (ILDL) above the P-type polysilicon gate region, a channel region separating each trench including epitaxial silicon, an N+ source region above the channel region extending between a top of each trench, and a source metal above the N+ source region.

In another general embodiment, a self-aligned trench structure JFET includes a silicon substrate, two or more trenches having an N-type polysilicon gate region near a bottom portion of the trench and an ILDL above the N-type polysilicon gate region, a channel region separating each trench including epitaxial silicon, a P+ source region above the channel region extending between a top of each trench, and a source metal above the P+ source region.

In accordance with another general embodiment, a method for producing a self-aligned trench structure JFET includes applying a mask to a substrate wherein the mask leaves portions of the substrate exposed, forming a trench in the exposed portions of the substrate, implanting a dopant into a bottom portion of the trench to form a P+ region, removing the mask, depositing a polysilicon into the trench, removing the polysilicon deposited above the top surface of the substrate, etching the polysilicon in the trench such that the polysilicon is recessed from a top surface of the substrate, depositing an ILDL into the trench above the polysilicon, forming a N+ source layer above the top surface of the substrate, and forming a source metal layer above the N+ source layer.

In another general embodiment, a method for producing a self-aligned trench structure JFET includes applying a mask to a substrate wherein the mask leaves portions of the substrate exposed, forming a trench in the exposed portions of the substrate, implanting a dopant into a bottom portion of the trench to form a N+ region, removing the mask, depositing a polysilicon into the trench, removing the polysilicon deposited above the top surface of the substrate, etching the polysilicon in the trench such that the polysilicon is recessed from a top surface of the substrate, depositing an ILDL into the trench above the polysilicon, forming a P+ source layer above the top surface of the substrate, and forming a source metal layer above the P+ source layer.

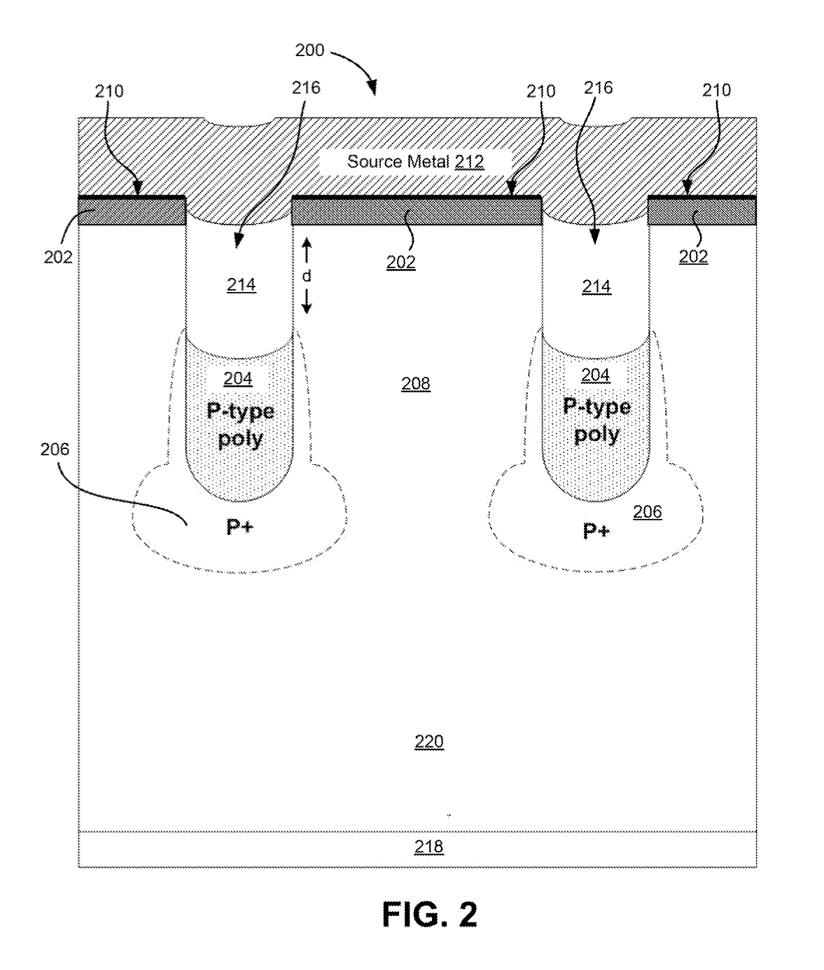

FIG. 2 illustrates a JFET 200 in accordance with one embodiment. To solve the previously described problem and/or push the JFET size to a lower limit, a JFET structure 200 that maintains the minimum distance d between the N+ of the source region 202 and the P-type polysilicon of the gate region 204 is provided, which also reduces the overall size of the JFET 200. As shown in FIG. 2, this is accomplished by restricting the P-type polysilicon in the gate region 204 to a lower portion of the trench 216, and forming the oxide layer 214 above the P-type polysilicon, instead of forming the top of the P-type polysilicon such that a surface lines up with the N+ source region 202, as seen in the prior art.

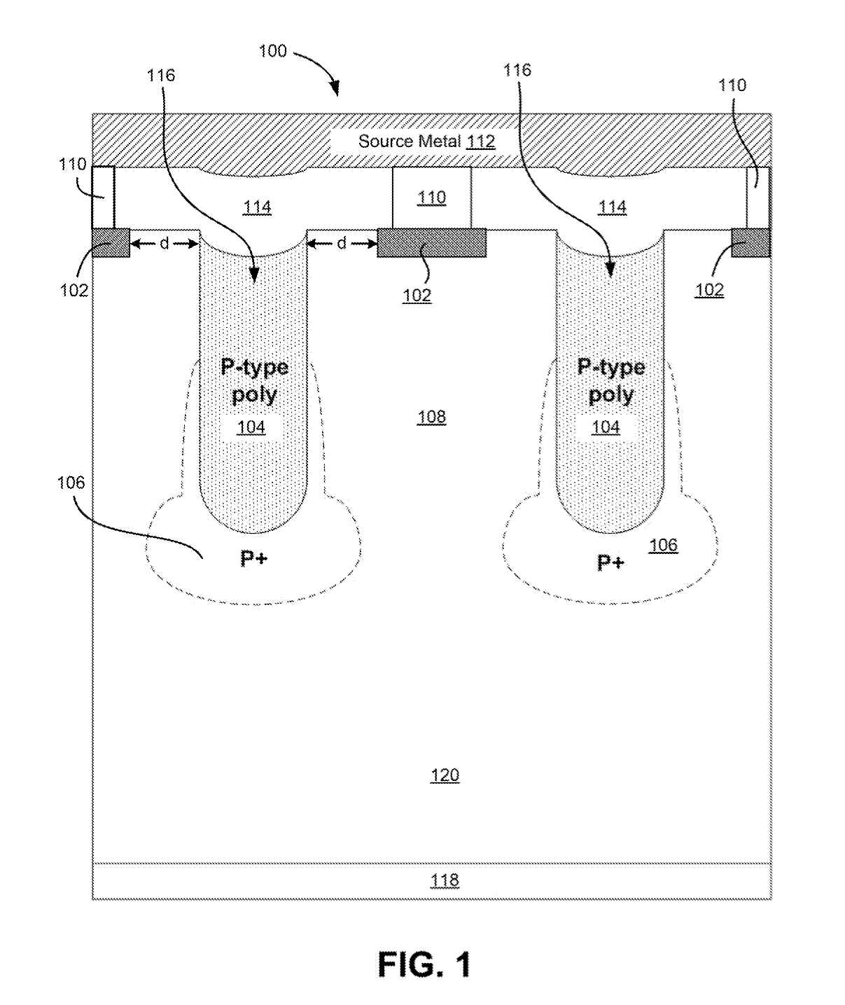

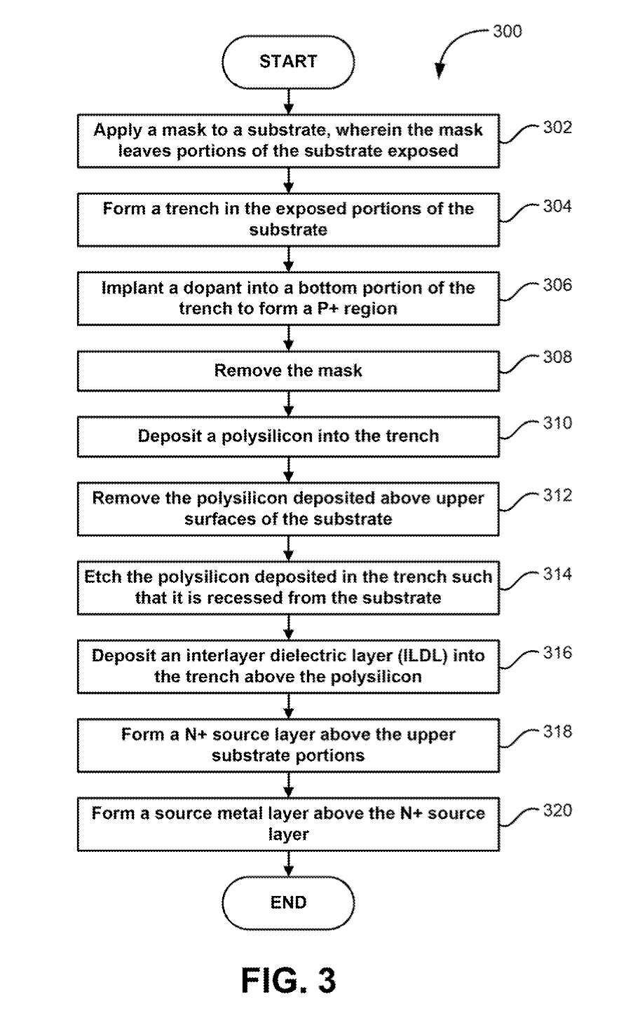

As illustrated in FIG. 2, instead of leaving a P-type polysilicon material upper surface substantially co-planar with the upper oxide surface as shown in FIG. 1, the JFET 200 in FIG. 2 has a recessed upper P-type polysilicon surface into the trench, deep enough to ensure a desired BV_{gss}. With the P-type polysilicon material recessed like this, the source region 202 may be maximized to occupy about the entire mesa area, minimizing the source resistance and maximizing the current path in the channel 208. In addition, the source region contact area 210 (the contact area between the source metal 212 and the source region 202) may be maximized and self-aligned, as described in relation to FIG. 3, described below.

Referring again to FIG. 2, the upper surface of the P-type polysilicon is a distance d away from the source region 202, which may comprise silicon, in one embodiment. In this way, the N+ material on the top in the center of the source region 202 (mesa) may extend to the edge of the trench 216, maximizing the channel 208 and the contact 210 between the source region 202 and the source metal 212. In this way, the electrical resistance may be minimized. In addition, this JFET structure 200 allows the contact 210 to be self-aligned. There is no need for the tungsten plug in the critical alignment in this area seen in the conventional JFET shown in FIG. 1.

Referring again to FIG. 2, the P-type polysilicon gate region 204 may comprise any conventional P-type poly material. Thus, though the gate region 204 is described herein as being a polysilicon layer, other materials known in the art may be substituted, as long as they are consistent and/or compatible with the materials selected for the other components.

In one approach, the source metal 212 may comprise aluminum and/or compounds thereof. In addition, a barrier metal layer (not shown) may be formed between the source region 202 and the source metal 212. The barrier metal layer may be comprised of any suitable material as would be known to one of skill in the art. For example, for a silicon/aluminum interface, the barrier metal layer may comprise titanium nitride, e.g., a thin layer of titanium on the source region 202, with a titanium nitride layer on the thin titanium layer, the titanium nitride layer contacting the source metal 212. Other barrier metals may be selected depending on the materials used for the source metal 212 and the source region 202, in various combinations. The barrier metal layer is intended to improve the contact 210 and reduce stress levels, in preferred embodiments.

In another embodiment, when the source metal 212 is an aluminum silicon copper alloy or some other alloy that can avoid spiking, the barrier metal layer may be omitted.

In more embodiments, the N+ source region 202 may comprise silicon in a compound having one or more of arsenic, phosphorous, antimony, etc. According to one embodiment, silicon is doped with a secondary element, such as arsenic, phosphorous, antimony, etc., in order to form a compound thereof.

According to one embodiment, the N epitaxial layer 220 may comprise epitaxial silicon or a compound thereof, silicon composites, silicon alloys, gallium composites, gallium nitrides, etc., such as silicon germanium (binary compound), silicon carbide (particularly for high voltage applications), gallium nitride, etc., according to various embodiments. In addition, the N+ substrate drain 218 may comprise silicon or a compound thereof having a slightly higher density that the N epitaxial layer 220.

In another embodiment, the oxide layer 214 may comprise silicon oxide formed through any method known in the art, such as thermally grown, deposited, etc.

The P+ region 206 may comprise silicon implanted with an element causing it to become P-type, such as boron, according to one embodiment. The element may be implanted via ion bombardment, according to one embodiment.

According to some embodiments, preferred dimensions may include some or all of the following illustrative dimensions. These dimensions are not meant to be limiting on the scope of the invention in any way, and are illustrative only.

In one embodiment, the depth of the trench 216 may be from about 0.5 micron to about 3 microns. In another embodiment, the width of the trench 216 may be from about 0.1 micron to about 0.5 micron, such as about 0.25 micron. According to various embodiments, an aspect ratio (depth/width) of the trench 216 may be about 10 or greater, such as 12, 15, 20, etc.

In addition, in some embodiments, the trench 216 has walls which are non-parallel, thereby creating a trench 216 which does not have vertical walls. For example, the walls may be tapered outward from vertical from a bottom of the trench 216 to a top of the trench 216, making it easier to fill the trench 216 with material during formation of the JFET 200, as a top of the trench 216 is wider than a bottom of the trench 216.

Additionally, a depth of the oxide layer 214 may correspond to a voltage region of the JFET 200. Therefore, the oxide layer 214 depth may vary depending on the voltage rating of the JFET 200. According to preferred embodiments, a thinnest oxide layer 214 that still provides a desired voltage rating of the JFET 200 may be used. As the desired voltage rating increases, the depth of the oxide layer 214 may also increase to provide this desired voltage capability.

In more embodiments, a thickness of the N+ source region 202 may be from about 0.1 micron to about 2 microns, depending on the desired breakdown voltage and materials of construction. In a further embodiment, the thickness of the N+ source region 202 may be about 0.25 micron.

Any of the layers described above may be deposited using any method known in the art, such as chemical vapor deposition (CVD), plasma enhanced vapor deposition (PEVD), sputtering, plating, etc.

According to various embodiments, N- and P-regions may be reversed. For example, the N-regions shown in FIG. 2 (N+ source region 202, N epitaxial layer 220, etc.) may be P-regions, and the P-regions shown in FIG. 2 (P+ region 206, P-type polysilicon of the gate region 204, etc.) may be N-regions. In this way, P can be pushed into N, or N may be pushed into P, as would be apparent to one of skill in the art upon reading the present descriptions.

Now referring to FIG. 3, a method 300 for forming a self-aligned contact trench JFET is shown according to one embodiment. The method 300 may be carried out in any desired environment, and may include more or less operations than those described below, according to various embodiments.

In operation 302, a mask is applied to a substrate leaving portions of the substrate exposed. The mask may be comprised of any material known in the art, and may be a hard mask or a soft mask, according to various embodiments.

In operation 304, a trench is formed in the exposed portions of the substrate. The trench may be formed via any technique known in the art, such as etching (dry or wet), milling, etc. In some embodiments, the trench may be formed to a depth of greater than about 0.5 micron and less than about 3 microns.

In operation 306, a dopant is implanted into a bottom portion of the trench to form a P+ region. Any technique known in the art may be used to implant the dopant, such as ion bombardment. The dopant, according to one embodiment, may comprise boron. According to some embodiments, bottom portions of walls of the trench may also be implanted with the dopant along with the bottom portion of the trench.

In operation 308, the mask is removed. Any method may be used to remove the mask as would be known to one of skill in the art, such as stripping, dissolving, etc.

In operation 310, a polysilicon is deposited into the trench. During this process, the polysilicon may be deposited full film, thereby also being deposited onto the top surface of the substrate.

According to one embodiment, the polysilicon, when deposited, may be P-type polysilicon. In an alternate embodiment, the polysilicon may be undoped when deposited, and then doped to make it P-type after being deposited into the trench. If the polysilicon is deposited undoped, the doping of the top surface of the substrate is minimal, and therefore does not adversely affect the performance of the JFET when formed.

In operation 312, the polysilicon deposited above the top surface of the substrate is removed. Any technique known in the art may be used to remove the polysilicon, such as a blank etch, chemical mechanical polish (CMP), etc.

In operation 314, the polysilicon in the trench is etched such that the polysilicon is recessed from the substrate. Any etching technique may be used as known in the art, as well as any other technique for removal of the polysilicon from the trench, as would be known to one of skill in the art.

In operation 316, an interlayer dielectric layer (ILDL) is deposited into the trench such that the ILDL fills the remaining portion of the trench. Any method known in the art may be used to deposit the ILDL, such as sputtering, CVD, PEVD, etc.

In some embodiments, the ILDL may be a silicon oxide or any other oxide of the substrate material.

In operation 318, an N+ source layer is formed above the top surface of the substrate. Any method known in the art may be used to form the N+ source layer, such as ion bombardment, doping, etc. In some embodiments, areas above the ILDL may also be doped N+, but this is not necessary or harmful to the performance of the JFET.

In operation 320, a source metal layer is formed above the N+ source layer. Any method known in the art may be used to deposit the source metal layer, such as sputtering, CVD, PEVD, etc.

According to preferred embodiments described herein, for a JFET rated at 100 volts, RDS×A (Resistance when on (Ω)×Contact Area) may be more than about 5 times less than that of a comparable JFET produced through conventional methods.

The above detailed description of embodiments of the present invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize.

The terminology used in the Detailed Description is intended to be interpreted in its broadest reasonable manner, even though it is being used in conjunction with a detailed description of certain specific embodiments of the invention. Certain terms may even be emphasized; however, any terminology intended to be interpreted in any restricted manner will be overtly and specifically defined as such in this Detailed Description section. In general, the terms used in the following claims should not be construed to limit the invention to the specific embodiments disclosed in the specification, unless the above Detailed Description section explicitly defines such terms. Accordingly, the actual scope of the invention encompasses not only the disclosed embodiments, but also all equivalent ways of practicing or implementing the invention under the claims.

What is claimed is:

1. A self-aligned trench structure junction gate field-effect transistor (JFET), comprising:
a silicon substrate;
two or more trenches, each trench comprising:
a P-type polysilicon gate region near a bottom portion of the trench; and
an interlayer dielectric layer (ILDL) above the P-type polysilicon gate region;
a channel region separating each trench, the channel region comprising epitaxial silicon;
an N+ source region above the channel region, the N+ source region extending between a top of each trench; and
a source metal above the N+ source region.

2. The JFET as recited in claim 1, further comprising a barrier metal layer between the N+ source region and the source metal.

3. The JFET as recited in claim 2,
wherein the barrier metal layer comprises titanium nitride,
wherein the N+ source region comprises silicon in a compound having at least one of: arsenic, phosphorous, and antimony, and
wherein the source metal comprises aluminum.

4. The JFET as recited in claim 1, wherein each trench has a depth of between about 0.5 micron to about 3 microns, and wherein each trench has a width between about 0.1 micron to about 0.5 micron.

5. The JFET as recited in claim 1, wherein walls of each trench taper outward from a bottom portion of the trench to an upper portion of the trench.

6. The JFET as recited in claim 1, wherein the silicon substrate comprises an N epitaxial silicon layer above an N+ silicon layer.

7. The JFET as recited in claim 6, wherein the N epitaxial silicon layer has a depth of between about 2 microns and about 12 microns.

8. The JFET as recited in claim 1, wherein the N+ source layer has a depth between about 0.25 micron and about 0.5 micron.

9. The JFET as recited in claim 1, wherein the source metal comprises an aluminum silicon copper alloy.

10. A self-aligned trench structure junction gate field-effect transistor (JFET), comprising:
a silicon substrate;
two or more trenches, each trench comprising:
an N-type polysilicon gate region near a bottom portion of the trench; and
an interlayer dielectric layer (ILDL) above the N-type polysilicon gate region;
a channel region separating each trench, the channel region comprising epitaxial silicon;
a P+ source region above the channel region, the P+ source region extending between a top of each trench; and
a source metal above the P+ source region.

11. A method for producing a self-aligned trench structure junction gate field-effect transistor (JFET), the method comprising:
applying a mask to a substrate, wherein the mask leaves portions of the substrate exposed;
forming a trench in the exposed portions of the substrate;
implanting a dopant into a bottom portion of the trench to form a P+ region;
removing the mask;
depositing a polysilicon into the trench;
removing the polysilicon deposited above the top surface of the substrate;
etching the polysilicon in the trench such that the polysilicon is recessed from a top surface of the substrate;
depositing an interlayer dielectric layer (ILDL) into the trench above the polysilicon;
forming a N+ source layer above the top surface of the substrate; and
forming a source metal layer above the N+ source layer.

12. The method as recited in claim 11, wherein the substrate comprises:
an upper portion comprising epitaxial silicon; and
a lower portion comprising silicon, and
wherein a depth of the epitaxial silicon is related to a desired breakdown voltage of the JFET.

13. The method as recited in claim 11, further comprising doping the polysilicon to form a P-type polysilicon.

14. The method as recited in claim 11, wherein the polysilicon comprises a P-type polysilicon when deposited.

15. The method as recited in claim 11, wherein the source metal layer comprises aluminum.

16. The method as recited in claim 15, further comprising forming a barrier metal layer between the source metal layer and the N+ source layer.

17. The method as recited in claim 16, wherein the barrier metal layer comprises titanium nitride.

18. The method as recited in claim 11, wherein the N+ source layer comprises silicon in a compound having at least one of: arsenic, phosphorous, and antimony.

19. The method as recited in claim 11, wherein implanting the dopant into the bottom portion of the trench comprises ion bombardment of boron into the trench.

20. The method as recited in claim 11, wherein a depth of the trench divided by a width of the trench is about 10 or greater.

21. A method for producing a self-aligned trench structure junction gate field-effect transistor (JFET), the method comprising:
applying a mask to a substrate, wherein the mask leaves portions of the substrate exposed;
forming a trench in the exposed portions of the substrate;
implanting a dopant into a bottom portion of the trench to form a N+ region;
removing the mask;
depositing a polysilicon into the trench;
removing the polysilicon deposited above the top surface of the substrate;
etching the polysilicon in the trench such that the polysilicon is recessed from a top surface of the substrate;
depositing an interlayer dielectric layer (ILDL) into the trench above the polysilicon;
forming a P+ source layer above the top surface of the substrate; and
forming a source metal layer above the P+ source layer.
